(19) United States
(12) Patent Application Publication
(10) Pub. No.: US 2026/0324383 A1
(43) Pub. Date: Oct. 15, 2026

(54) GATE METAL OXIDATION PROTECTION METHODS

(71) Applicant: Applied Materials, Inc., Santa Clara, CA (US)

(72) Inventors: Kent Qiujing ZHAO, San Francisco, CA (US); Albert KIM, Santa Clara, CA (US); Bo XIE, San Jose, CA (US); Chi-I LANG, Cupertino, CA (US); Li-Qun XIA, Cupertino, CA (US)

(21) Appl. No.: 19/176,908

(22) Filed: Apr. 11, 2025

(51) Int. Cl. H01L 21/768; H01L 23/522

(52) U.S. Cl. CPC H10W 20/077; H10W 20/056; H10W 20/081; H10W 20/42

(57) ABSTRACT

Embodiments described herein relate to metal gate transistor devices, and methods of preventing oxidation thereof. In one or more embodiments, a device is provided. The device includes a conductive layer. A silicon-containing passivation layer is disposed over the conductive layer. An etch stop layer having silicon, carbon, oxygen, and nitrogen, is disposed over the silicon-containing passivation layer. An oxide layer is disposed over the etch stop layer. The silicon-containing passivation layer and the etch stop layer have an opening disposed therethrough, and a metal fill is disposed within the opening.

### BACKGROUND

### Field

Embodiments of the present disclosure generally relate to a metal gate transistor. More specifically, embodiments herein relate to a metal gate transistor having a silicon-containing passivation layer, an etch stop layer, and an oxide layer, and methods of forming the same.

### Description of the Related Art

Metal gate oxidation in semiconductor manufacturing refers to a process where a thin layer of oxide is formed on the surface of a metal gate electrode. This process is one stage in the fabrication of metal gate transistors, which is used in advanced semiconductor technologies to improve device performance and reduce power consumption. The metal gate oxidation process includes metal gate formation and oxidation.

Initially, a thin layer of metal, such as tungsten (W), titanium (Ti), or a metal alloy, is deposited onto the semiconductor substrate to form the gate electrode of the transistor. This metal gate serves as a key component in the transistor structure, controlling the flow of electrical current between the source and drain regions.

After the metal gate is formed, the metal gate undergoes an oxidation process where a thin layer of oxide is grown on its surface. This oxide layer, typically silicon dioxide (SiO₂), is formed by exposing the metal gate to an oxidizing environment, such as oxygen (O₂) or ozone (O₃), at elevated temperatures. The oxidation process converts a portion of the metal gate surface into oxide, creating a stable interface between the metal gate and the surrounding dielectric materials.

Metal gate oxidation serves several purposes in semiconductor manufacturing. For example, metal gate oxidation provides electrical insulation between the metal gate and the surrounding dielectric materials, preventing unwanted leakage currents and ensuring proper transistor operation. Metal gate oxidation helps to improve the reliability and stability of the transistor by reducing interface defects and trapping charges at the gate dielectric interface. Metal gate oxidation enhances the compatibility of the metal gate with subsequent process stages, such as gate dielectric deposition and contact formation, by providing a uniform and stable surface for further processing.

As semiconductor technology advances towards nodes as small as 1.4 nanometers (nm) and beyond, the control of metal gate oxidation becomes increasingly challenging due to the ultra-thin dimensions involved. Achieving precise control over the metal gate oxidation process at such scales calls for innovative techniques and stringent process optimization. In the 1.4 nm node and beyond, controlling the extent of metal gate oxidation will be key in developing smaller and smaller semiconductor devices.

Therefore, there is a need for improved methods to precisely control metal gate oxidation by minimizing or preventing unwanted oxidation.

### SUMMARY

In one or more embodiments, a device is provided. The device includes a conductive layer. A silicon-containing passivation layer is disposed over the conductive layer. An etch stop layer having silicon, carbon, oxygen, and nitrogen, is disposed over the silicon-containing passivation layer. An oxide layer is disposed over the etch stop layer. The silicon-containing passivation layer and the etch stop layer have an opening disposed therethrough, and a metal fill is disposed within the opening.

In one or more embodiments, a method is provided. The method includes positioning a conductive layer disposed on a substrate in a process chamber. A silane soak operation is performed to form a silicon-containing passivation layer on the conductive layer. An etch stop layer deposition operation is performed to deposit an etch stop layer. An oxide deposition operation is performed to deposit an oxide layer. The oxide layer, etch stop layer, and silicon-containing passivation layer are etched to form an opening therethrough. The opening is filled with a metal fill.

In one or more embodiments, a method is provided. The method includes positioning a conductive layer disposed on a substrate in a process chamber. A silane soak operation is performed to form a silicon-containing passivation layer on the conductive layer. The silane soak operation includes flowing a silane gas at a flow rate of about 10 standard cubic centimeters per minute (sccm) to about 1,000 sccm, and increasing a temperature of the process chamber to about 300 °C to about 450 °C. An etch stop layer deposition operation is performed to deposit an etch stop layer. The etch stop layer deposition operation includes flowing a first gas mixture at a first flow rate, and a reducing agent at a second flow rate. The first gas mixture includes silicon, carbon, oxygen, and nitrogen. The ratio of the first flow rate and the second flow rate is about 1:1 to about 100:1. An oxygen-free plasma deposition operation is performed to deposit an oxide layer. The oxygen-free plasma deposition operation includes flowing an oxygen containing precursor at a third flow rate and a carrier gas at a fourth flow rate. The oxide layer, the etch stop layer, and the silicon-containing passivation layer are etched to from an opening therethrough. The opening is filled with a metal fill.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is schematic, cross-sectional view of a device, according to one or more embodiments.

FIG. 2 is a schematic, cross-sectional view of a process chamber, according to one or more embodiments.

FIG. 3 is a flow diagram illustrating operations of a method for fabricating a device according to one or more embodiments.

FIG. 4A-4F are schematic, cross-sectional views of a metal gate during a method of forming the metal gate transistor, according to embodiments herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a metal gate transistor having a passivation layer disposed over a conductive layer, an etch stop layer (ESL) disposed over the passivation layer, and an oxide layer disposed over the ESL. These example embodiments minimize or prevent unwanted metal gate oxidation through different methods of forming the passivation layer, the ESL deposition, and the oxide layer deposition. In one example, which may be combined with other examples, the passivation layer is disposed over the metal gate through a silane (SiH₄) soak operation, minimizing or preventing metal gate oxidation during subsequent ESL film deposition. In another example, which may be combined with other examples, a reducing agent, such as hydrogen (H₂) is added to the ESL during the ESL film deposition. In another example, which may be combined with other examples, oxygen free plasma is used to deposit the oxide layer in an oxygen free plasma deposition operation. Overall, as noted above, preventing unwanted metal gate oxidation is beneficial for ensuring the performance, reliability, and manufacturability of semiconductor devices, especially in advanced technologies where gate stack engineering plays a significant role in device characteristics

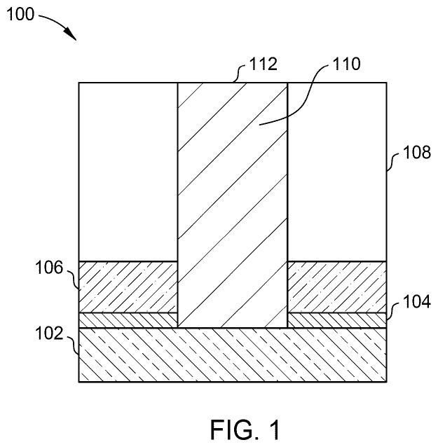

FIG. 1 is schematic, cross-sectional view of a device 100 according to one or more embodiments of the present disclosure. The device 100 is a metal gate transistor. The device includes a conductive layer 102, a passivation layer 104, an etch stop layer (ESL) 106, an oxide layer 108, an opening 110, and a metal fill 112 disposed within the opening 110.

The conductive layer 102 is at a distal end of the device 100. The conductive layer 102 may be referred to as a metal gate. The conductive layer 102 is a layer of metal. The conductive layer 102 may be tungsten (W), titanium (Ti), cobalt (Co), copper (Cu), nickel (Ni), ruthenium (Ru), aluminum (Al), tantalum (Ta), molybdenum (Mo), a metal alloy, or combinations thereof. The conductive layer 102 may be deposited, on a substrate (not shown), by any suitable deposition method, including chemical vapor deposition (CVD), plasma-enhanced chemical vapor deposition (PECVD), atomic layer deposition (ALD), electrochemical deposition, electroless deposition, or any combination thereof.

The passivation layer 104 is disposed over the conductive layer 102. The passivation layer 104 is disposed over the conductive layer 102 using a silane (SiH₄) soak operation. In some embodiments where the conductive layer 102 is made of tungsten, the passivation layer 104 is a tungsten silicide, having the chemical formula WSi_{x.} In other embodiments where the conductive layer 102 is made of titanium, the passivation layer 104 is a titanium silicide having the chemical formula TiSiₓ.

An etch stop layer (ESL) 106 is disposed over the passivation layer 104. The ESL 106 is a SiCON film. The ESL 106 acts as a protective barrier for the conductive layer 102 in subsequent etching operations by preventing damage to the conductive layer 102 during etching. The ESL 106 can be deposited to a thickness of about 30 angstroms to about 90 angstroms. For example, the ESL 106 may be deposited to a thickness of about 30 angstroms to about 50 angstroms, about 50 angstroms to about 70 angstroms, or about 70 angstroms to about 90 angstroms.

The SiCON film, also known as silicon carbon oxynitride, is a type of dielectric material used in semiconductor manufacturing processes. SiCON film is a composite material consisting of silicon (Si), carbon (C), oxygen (O), and nitrogen (N) atoms. As a SiCON film, the ESL 106 is an oxygen-containing film. The oxygen of the ESL 106 may oxidize the conductive layer 102 as the ESL 106 is disposed thereon. Therefore, the passivation layer 104 is first disposed over the conductive layer 102 to minimize or prevent oxidation of the conductive layer 102. Thus, the passivation layer 104 acts as a monolayer barrier between the conductive layer 102 and the ESL 106. The monolayer properties of the passivation layer 104 minimizes or prevents oxidation of the conductive layer 102 as the ESL 106 is disposed thereon.

An oxide layer 108 is disposed over the ESL 106. In some embodiments, the oxide layer 108 is silicon dioxide (SiO₂). In some embodiments, the oxide layer 108 may be deposited through an oxygen-free plasma deposition operation. The term “oxygen-free plasma” refers to the gas sources of the chamber being oxygen free or devoid of oxygen. Therefore, plasma is generated using a gas or gas mixtures in the chamber with no oxygen. In other words, the plasma includes no O₂ or O₃. After the plasma is generated in the chamber without oxygen, an oxygen-containing precursor is introduced. By excluding oxygen from the plasma itself, unwanted metal gate oxidation can be minimized or prevented.

An opening 110 is formed on top of the conductive layer 102, and through the passivation layer 104, the ESL 106, and the oxide layer 108. The opening 110 may be formed through an etching operation. The opening has a metal fill 112 disposed therethrough. The metal fill 112 contacts the top of the conductive layer 102, and each of the ESL 106 and the oxide layer 108. The metal fill 112 may be deposited through a metal fill operation. Metals used for the metal fill operation include at least copper (Cu) and tungsten (W).

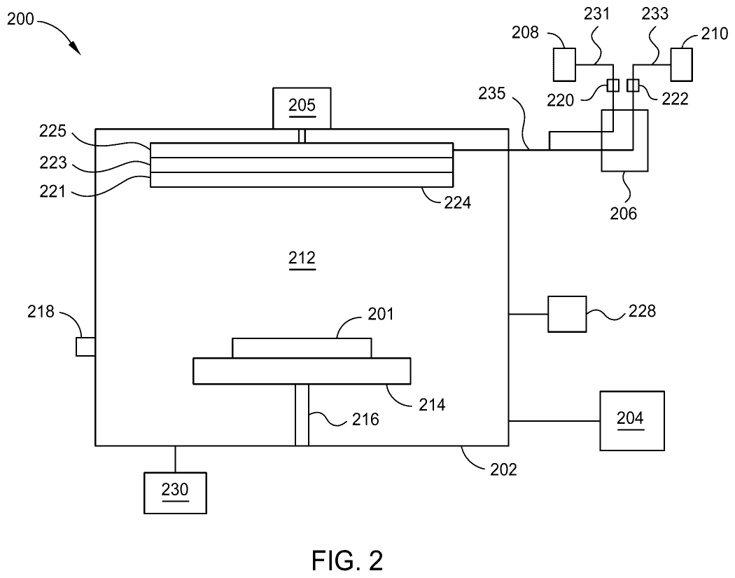

FIG. 2 illustrates a schematic cross-sectional view of a process chamber 200, such as a plasma enhanced chemical vapor deposition (PECVD) chamber, utilized during one or more methods for forming a metal gate. The process chamber 200 includes a chamber body 202 coupled to a vacuum pump 204 and an input manifold 206 coupled to a first gas source 208 and a second gas source 210. The chamber body 202 defines or otherwise contains a process region 212 that includes a pedestal 214 disposed therein to support a substrate 201. The pedestal 214 includes heating elements (not shown) and a mechanism (not shown) that retains the substrate 201 on the pedestal 214, such as an electrostatic chuck, a vacuum chuck, a substrate retaining clamp, or the like. The pedestal 214 is coupled to and movably disposed in the process region 212 by a stem 216 connected to a lift chamber (not shown) that moves the pedestal 214 between an elevated processing position and a lowered position that facilitates transfer of the substrate 201 to and from the process chamber 200 through an opening 218 of the chamber body 202.

A flow controller 220, such as a mass flow control (MFC) device, is disposed between the first gas source 208 and the input manifold 206 to control a flow of first process gases from the first gas source 208 to a showerhead assembly 224, used for distributing the first process gases across the process region 212. The showerhead assembly 224 can include a faceplate 221, a blocker plate 223, and a gas box 225, as depicted in FIG. 2. The first and second process gases can be maintained separately through the input manifold 206 and subsequently combined just upstream of the gas box 225.

In one or more examples, a flow of the first process gas via line 231 is transferred from the first gas source 208 through the input manifold 206, a flow of the second process gas via line 233 is transferred from the second gas source 210 through the input manifold 206, and both the flow of the first process gas via line 231 and the flow of the second process gas via line 233 are combined to produce a flow of a third process gas via line 235 prior to being introduced into the gas box 225 and eventually into the process region 212.

The flow of the third process gas via line 235 can be maintained at a temperature low enough to keep some the precursors (e.g., diborane, silane, and/or ammonia) from reacting in the lines and causing dusting or particulate throughout the showerhead assembly 224, the process region 212, and/or on the substrate 201.

According to one or more embodiments, which can be combined with other embodiments described herein, the first process gas includes at least one or more precursors, and one or more carrier and/or process gases (e.g., helium, argon, hydrogen). For example, the first process gas may include silane (SiH₄), dimethoxydimethylsilane (DMDMOS), trimethylsilane ((CH₃)₃SiH) (ammonia (NH₃), nitrous oxide (N₂O ), argon (Ar), hydrogen (H₂), carbon monoxide (CO), helium (He) or combinations thereof. A second controller 222 is disposed between the second gas source 210 and the input manifold 206 to control a second flow of a second process gases from the second gas source 210 to the showerhead assembly 224 for distributing the second process gas across the process region 212. According to one or more embodiments, which can be combined with other embodiments described herein, the second process gas includes at least one or more precursors, and one or more carrier and/or process gases (e.g., helium, argon, hydrogen). For example, the second process gas may include SiH₄, DMDMOS, trimethylsilane, NH₃, N₂O , Ar, H₂, CO, He or combinations thereof.

The showerhead assembly 224 is coupled to and in fluid communication with a remote plasma system (RPS) 205. The RPS 205 can be used to form a plasma in the process region 212 from the first and second process gases in the process region 212. In some examples, the plasma is ignited or otherwise generated in the RPS 205 disposed outside of the chamber body 202. The plasma is transferred or otherwise introduced the process region 212 while depositing the silicon boron nitride layer on the substrate 201.

A third gas source 228 can be coupled to the chamber body 202 for providing additional process gas to control the pressure within the process region 212. A controller 230 is coupled to the process chamber 200 and configured to control process conditions of the process chamber 200 during a deposition operation or other operations.

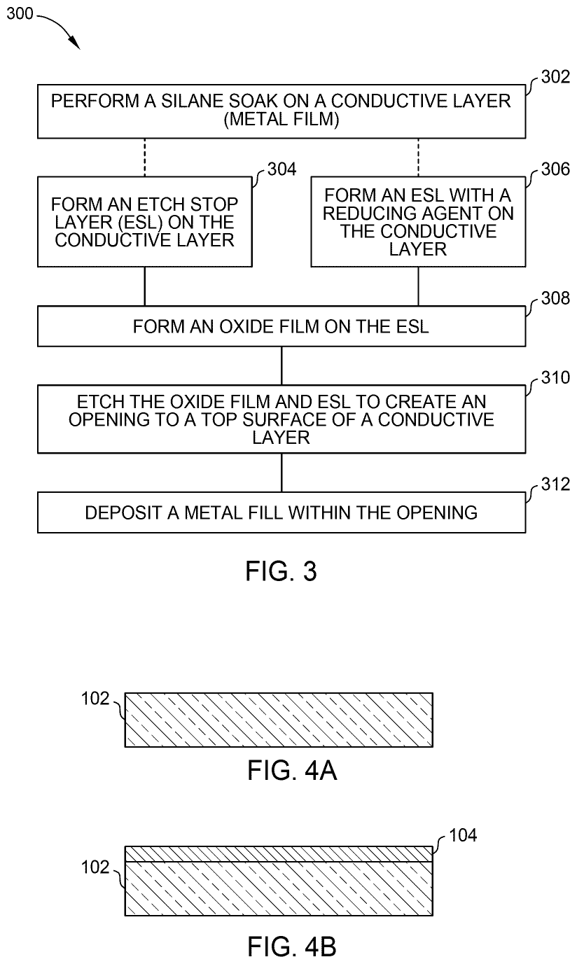

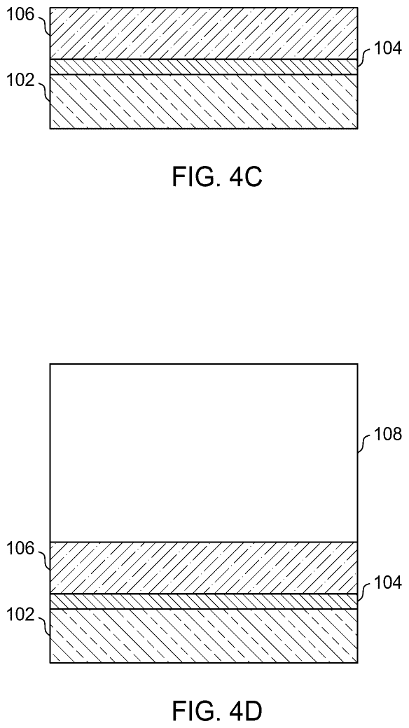

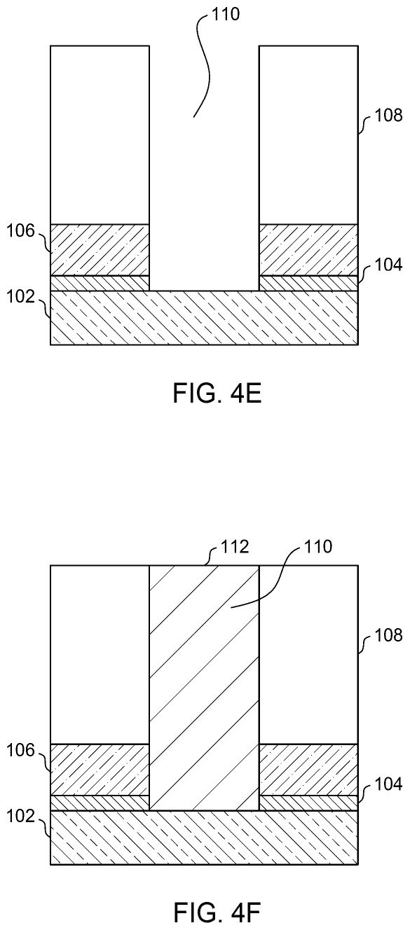

FIG. 3 illustrates a process flow diagram of a method 300 of forming the device 100 according to one or more embodiments of the present disclosure. FIGS. 3A-3E are schematic views of the conductive layer 102 during the method 300 of forming the device 100.

At optional operation 302, as shown in FIGS. 3A and 3B, a conductive layer 102, which may be disposed on a substrate (not shown), is positioned in a process chamber (e.g., the process chamber 200), and a silane soak is performed. During optional operation 302, SiH₄ is introduced into the process region 212 with the conductive layer 102 therein.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor substrates. Substrates may be exposed to a pretreatment process to polish, etch, reduce, oxidize, hydroxylate, anneal and/or bake the substrate surface. In addition to film processing directly on the surface of the substrate, any of the film processing steps disclosed may also be performed on an under-layer formed on the substrate as disclosed in more detail below, and the term “substrate surface” is intended to include such under-layer as the context indicates. Thus for example, where a film/layer or partial film/layer has been deposited onto a substrate surface, the exposed surface of the newly deposited film/layer becomes the substrate surface.

In certain embodiments, conductive layer 102 is a layer of metal. The conductive layer 102 may be tungsten (W), titanium (Ti), cobalt (Co), copper (Cu), nickel (Ni), ruthenium (Ru), aluminum (Al), tantalum (Ta), molybdenum (Mo), a metal alloy, or combinations thereof. The conductive layer 102 may be deposited onto the surface of the substrate by any suitable deposition method, including chemical vapor deposition (CVD), plasma-enhanced chemical vapor deposition (PECVD), atomic layer deposition (ALD), electrochemical deposition, electroless deposition, or any combination thereof.

In general, the following exemplary silane soak operation parameters may be used to treat the conductive layer 102. The pressure within the process chamber (e.g., the process chamber 200) may range from about 3 Torr to about 30 Torr. For example, the pressure within the process chamber may be from about 3 Torr to about 10 Torr, about 10 Torr to about 20 Torr, or about 20 Torr to about 30 Torr. The process parameters may range from a processing temperature of about 300° Celsius to about 450° Celsius. For example, the processing temperature may be from about 300° Celsius to about 350° Celsius, about 350° Celsius to about 400° Celsius, or about 400° Celsius to about 450° Celsius.

The SiH₄ is flowed into the process region 212 at a flow rate of about 10 standard cubic centimeters per minute (sccm) to about 1,000 sccm. For example, the SiH₄ flow rate is about 10 sccm to about 300 sccm, about 300 sccm to about 700 sccm, or about 700 sccm to about 1,000 sccm. In some embodiments, the SiH₄ is introduced into the process region 212 with a carrier gas, such as He. The silane soak operation time may range from about 30 seconds to about 300 seconds. For example, the silane soak operation time may be from about 30 seconds to 100 seconds, about 100 seconds to about 200 seconds, or about 200 seconds to about 300 seconds.

The silane soak of optional operation 302 forms a passivation layer 104 on the conductive layer 102. In some embodiments where the conductive layer 102 is made of tungsten, the passivation layer 104 is a tungsten silicide, having the chemical formula WSiₓ. In other embodiments where the conductive layer 102 is made of titanium, the passivation layer 104 is a titanium silicide having the chemical formula TiSiₓ. The passivation layer 104 is a monolayer. The passivation layer 104 may be deposited to a thickness of about 1 nanometer to about 2 nanometers. The process region 212 may be purged after optional operation 302, and before operation 304 or operation 306.

In operation 304 and operation 306, as shown in FIG. 3C and FIG. 3D, respectively, the ESL 106 is disposed over the conductive layer 102. The ESL 106 is a SiCON film. Absent the passivation layer 104, the oxygen of the ESL 106 may react with the conductive layer 102 as it is disposed thereon. Accordingly, disposing the ESL 106 over the conductive layer 102 can lead to oxidation of the conductive layer 102. Optional operation 302 disposes the passivation layer 104 on the conductive layer 102 before the ESL 106 is disposed thereon. Thus, the passivation layer 104 acts as a metal monolayer barrier. The monolayer properties of the passivation layer 104 minimizes or prevents oxidation of the conductive layer 102 as the ESL 106 is disposed thereon.

Operation 304 and operation 306 are ESL deposition operations. Operation 304 and 306 deposit an ESL 106 over the conductive layer 102. In operation 304, a SiCON precursor is flowed and energized to form the ESL 106. In operation 306, a SiCON precursor and a reducing agent are flowed and energized to form the ESL 106. In some embodiments, the reducing agent may be hydrogen gas (H₂), carbon monoxide (CO), or combinations thereof. The reducing agent aids in reducing oxidation of the underlying conductive layer 102 that the ESL 106 is disposed over.

During operation 304, an ESL 106 is disposed over the conductive layer 102. In some embodiments including optional operation 302, the ESL 106 is disposed over the conductive layer 102 with the passivation layer 104 thereon. The ESL 106 is a SiCON film.

In the example embodiments, gas precursors are used to introduce silicon, oxygen, carbon, and nitrogen atoms onto the substrate surface, allowing for the controlled formation of SiCON films with specific properties. These gas precursors are typically organic compounds containing silicon, carbon, and oxygen functional groups, along with nitrogen atoms. In some embodiments, the gas precursors include dimethoxydimethylsilane (DMDMOS) and ammonia (NH₃). During the ESL deposition operation, the gas precursors are introduced into the chamber along with a carrier gas and, if applicable, other reactive gases. In some embodiments, the carrier gas is a He gas. Depending on the deposition conditions and parameters such as temperature, pressure, and RF power, the precursor undergoes chemical reactions to form a SiCON film on the substrate surface. The ESL 106 is deposited, for example, through a plasma-enhanced chemical vapor deposition (PECVD) process.

In general, the following exemplary ESL deposition parameters may be used to dispose the ESL 106 over the conductive layer 102 and, in some embodiments, the passivation layer 104 thereon. The pressure within the process chamber (e.g., the process chamber 200) may range from about 2 Torr to about 20 Torr. For example, the pressure within the process chamber may be from about 2 Torr to about 8 Torr, about 8 Torr to about 14 Torr, or about 14 Torr to about 20 Torr. The process parameters may range from a processing temperature of about 300° Celsius to about 450° Celsius. For example, the processing temperature may be from about 300° Celsius to about 350° Celsius, about 350° Celsius to about 400° Celsius, or about 400° Celsius to about 450° Celsius.

The precursor gases are flowed into the process region at a flow rate of about 100 milligrams per minute (mg/min) to about 2,000 mg/min For example, the precursor flow rate is about 100 mg/min to about 500 mg/min, about 500 mg/min to about 1,000 mg/min, about 1,000 mg/min to about 1,500 mg/min, or about 1,500 mg/min to about 2,000 mg/min. A He carrier gas is flowed into the processing region at a carrier gas flow rate of about 500 sccm to about 5,000 sccm. For example, the carrier gas flow rate is about 500 to about 2,000 sccm, about 2,000 sccm to about 3,500 sccm, or about 3,500 sccm to about 5,000 sccm. An RF power is applied to the precursor gases within the process chamber 200. The power level may range from about 0.14 watts/cm² to about 1.4 watts/cm². For example, the power level may be about 0.14 watts/cm² to about 0.5 watts/cm², about 0.5 watts/cm² to about 1 watts/cm², or about 1 watts/cm² to about 1.4 watts/cm².

At operation 306, as shown in FIG. 3D, the ESL 106 is formed using a reducing agent. In some embodiments, including optional operation 302, the ESL 106, containing the reducing agent, is disposed over the conductive layer 102 with the passivation layer 104 thereon. During operation 306, the precursor and the reducing agent are flowed into the process chamber 200 to deposit the ESL 106 containing the reducing agent. The precursor and the reducing agent may be co-flowed at the same time. Alternatively, the reducing agent may be flowed before the precursor. In some embodiments, the reducing agent may be H₂ or CO.

In general, the following exemplary parameters may be used to dispose the ESL 106, containing the reducing agent, over the conductive layer 102. The pressure within the process chamber (e.g., the process chamber 200) may range from about 2 Torr to about 20 Torr. For example, the pressure within the process chamber may be from about 2 Torr to about 8 Torr, about 8 Torr to about 14 Torr, or about 14 Torr to about 20 Torr. The process parameters may range from a processing temperature of about 300° Celsius to about 450° Celsius. For example, the processing temperature may be from about 300° Celsius to about 350° Celsius, about 350° Celsius to about 400° Celsius, or about 400° Celsius to about 450° Celsius.

The precursor is flowed into the process region at a flow rate of about of about 500 sccm to about 10,000 sccm. For example, the precursor flow rate is about 500 sccm to about 2,500 sccm, about 2,500 sccm to about 5,000 sccm, about 5,000 sccm to about 7,500 sccm, or about 7,500 sccm to about 10,000 sccm. The reducing agent is flowed into the process region at a flow rate of about 100 sccm to about 500 sccm. For example, the reducing agent flow rate may be from 100 sccm to about 250 sccm, about 250 sccm to about 350 sccm, or about 350 sccm to about 500 sccm. The precursor and the reducing agent may be flowed at a flow ratio defined as the volumetric flow rate of the precursor measured in sccm, P_{sccm}, to the volumetric flow rate of the reducing agent measured in sccm, R_{sccm}, (P_{sccm}: R_{sccm}). In some embodiments, the flow ratio is about 1:1 to about 100:1. For example, the flow ratio may be about 1:1 to about 25:1, about 25:1 to about 50:1, about 50:1 to about 75:1, or about 75:1 to about 100:1. An RF power is applied to the precursor and the reducing agent within the process chamber 200. The power level may range from about 0.14 watts/cm² to about 1.4 watts/cm². For example, the power level may be about 0.14 watts/cm² to about 0.5 watts/cm², about 0.5 watts/cm² to about 1 watts/cm², or about 1 watts/cm² to about 1.4 watts/cm².

Introducing the reducing agent during the deposition operation minimizes or prevents oxidation of the conductive layer 102. The resulting film is a SiCON film. The thickness of the reducing agent containing ESL 106 may range from about 30 angstroms to about 90 angstroms. The resulting ESL 106 containing the reducing agent is thicker than the ESL 106 of operation 304.

At operation 308, as shown in FIG. 3D, an oxide deposition operation is performed to deposit an oxide layer 108 over the ESL 106. The oxide layer 108 can be an oxide film. The oxide film can be, e.g., a silicon dioxide (SiO₂). In some embodiments, operation 308 is an oxygen-free plasma deposition operation. In some embodiments, the oxygen containing precursor includes SiH₄ and N₂O.

In one embodiment, the oxide layer 108 is formed using an oxygen containing precursor and He carrier gas. The processing temperature is about 200 °C to about 400 °C. The pressure within the process chamber (e.g., the process chamber 200) is about 7.5 Pascal (Pa) to about 50 Pa. The RF power applied is about 300 Watts to about 1,000 Watts. The liquid flow or flow of the oxygen containing precursor is about 100 sccm to about 2,000 sccm, and the He gas flow is about 200 sccm to about 5,000 sccm.

In another embodiment, the oxide layer 108 is formed using an using an oxygen containing precursor with He carrier gas and H₂ gas or using an oxygen containing precursor with argon (Ar) carrier gas and H₂ gas. The H₂ gas is configured to remove carbon (C) from the oxygen containing precursor. The processing temperature is about 200 °C to about 400 °C. The pressure within the process chamber (e.g., the process chamber 200) is about 7.5 Pa to about 50 Pa. The RF power applied is about 300 Watts to about 1,000 Watts. The liquid flow or flow of the oxygen containing precursor is about 100 sccm to about 2,000 sccm. The He gas flow is about 200 sccm to about 5,000 sccm and the Ar gas flow is about 200 to about 5,000 sccm. The H₂ gas flow is about 50 sccm to about 3,000 sccm.

In another embodiment, the oxide layer 108 is formed using an oxygen containing precursor and Ar carrier gas. The processing temperature is about 200 °C to about 400 °C. The pressure within the process chamber (e.g., the process chamber 200) is about 7.5 Pa to about 50 Pa. The RF power applied is about 300 Watts to about 1,000 Watts. The liquid flow or flow of the oxygen containing precursor is about 100 sccm to about 2,000 sccm, and the argon gas flow is about 200 sccm to about 5,000 sccm.

At operation 310, as shown in FIG. 3E, the oxide layer 108, the ESL 106, and the passivation layer 104 are etched to a top surface of the conductive layer 102, so that the opening 110 is formed. The etching process is conducted using a perfluorocarbon (PFC) gas having a chemical formula of CₓF_{y}.

At operation 312, as shown in FIG. 3F, a metal fill operation is performed. Examples of metals used for the metal fill include at least copper (Cu) and tungsten (W). The metal fill 112 may be deposited using plasma-enhanced chemical vapor deposition (PECVD) or chemical vapor deposition (CVD).

Benefits of the present disclosure include a passivation layer that helps minimize or prevent oxidation of an underlying metal conductive layer when a subsequent ESL deposition operation is conducted thereon. Additionally, flowing a reducing agent during the ESL deposition operation aids in minimizing or preventing oxidation of the underlying conductive layer. Further, conducting the oxide layer deposition operation using an oxygen free plasma helps minimize or prevent oxidation of the metal conductive layer.

While the foregoing is directed to embodiments of the present disclosure, other and further embodiments of the disclosure may be devised without departing from the basic scope thereof, and the scope thereof is determined by the claims that follow.

What is claimed is:

1. A device, comprising:
a conductive layer;
a silicon-containing passivation layer over the conductive layer;
an etch stop layer over the silicon-containing passivation layer, the etch stop layer including silicon (Si), carbon (C), oxygen (O), and nitrogen (N);
an oxide layer over the etch stop layer; and
an opening, the opening disposed throughout the silicon-containing passivation layer and the etch stop layer, the opening having a metal fill disposed therethrough.

2. The device of claim 1, wherein the conductive layer is made of tungsten (W), titanium (Ti), cobalt (Co), copper (Cu), nickel (Ni), ruthenium (Ru), aluminum (Al), tantalum (Ta), molybdenum (Mo), a metal alloy, or combinations thereof.

3. The device of claim 1, wherein the oxide layer is deposited through an oxygen-free plasma deposition operation.

4. The device of claim 1, wherein the silicon-containing passivation layer is disposed through a silane (SiH₄) soak operation.

5. The device of claim 1, wherein the metal fill includes at least copper (Cu) and tungsten (W).

6. The device of claim 1, wherein the oxide layer is silicon dioxide (SiO₂).

7. The device of claim 1, wherein the etch stop layer further includes a reducing agent.

8. The device of claim 7, wherein the reducing agent is hydrogen (H₂), carbon monoxide (CO), or combinations thereof.

9. A method comprising:
positioning a conductive layer disposed on a substrate in a process chamber;
performing a silane (SiH₄) soak operation to form a silicon-containing passivation layer over the conductive layer;
performing an etch stop layer (ESL) deposition operation to deposit an ESL;
performing an oxide deposition operation to deposit an oxide layer;
etching the oxide layer, the etch stop layer, and the silicon-containing passivation layer to form an opening therethrough; and
filling the opening with a metal fill.

10. The method of claim 9, wherein the ESL deposition operation further comprises:
flowing a first gas mixture at a first flow rate, the first gas mixture including silicon (Si), carbon (C), oxygen (O), and nitrogen (N); and
flowing a reducing agent at a second flow rate.

11. The method of claim 10, wherein a ratio of the first flow rate to the second flow rate is about 1:1 to about 100:1.

12. The method of claim 10, wherein the reducing agent is hydrogen (H₂), carbon monoxide (CO), or combinations thereof.

13. The method of claim 9, wherein the oxide deposition operation is an oxygen-free plasma deposition operation comprising:
flowing an oxygen containing precursor at a third flow rate; and
flowing a carrier gas at a fourth flow rate.

14. The method of claim 13, wherein the carrier gas is helium (He).

15. The method of claim 9, wherein the silane soak operation includes flowing SiH₄ gas at a SiH₄ gas flow rate of about 10 sccm to about 1,000 sccm, and is conducted at a processing temperature of about 300 °C to about 450 °C.

16. The method of claim 9, wherein the conductive layer is made of tungsten (W), titanium (Ti), cobalt (Co), copper (Cu), nickel (Ni), ruthenium (Ru), aluminum (Al), tantalum (Ta), molybdenum (Mo), a metal alloy, or combinations thereof.

17. A method comprising:
positioning a conductive layer disposed on a substrate in a process chamber;
performing a silane (SiH₄) soak operation to form a silicon-containing passivation layer over the conductive layer, the silane soak operation comprising:
flowing SiH₄ gas at a SiH₄ gas flow rate of about 10 standard cubic centimeters per minute (sccm) to about 1,000 sccm; and
increasing a temperature of the process chamber to about 300 °C to about 450 °C;
conducting an etch stop layer (ESL) deposition operation to deposit an ESL, the ESL deposition operation comprising:
flowing a first gas mixture at a first flow rate, the first gas mixture including silicon (Si), carbon (C), oxygen (O), and nitrogen (N); and
flowing a reducing agent at a second flow rate, wherein a ratio of the first flow rate to the second flow rate is about 1:1 to about 100:1;
conducting an oxygen-free plasma deposition operation to deposit an oxide layer, the oxygen-free plasma deposition operation comprising:
flowing an oxygen containing precursor at a third flow rate; and
flowing a carrier gas at a fourth flow rate;
etching the oxide layer, the etch stop layer, and the silicon-containing passivation layer to form an opening therethrough; and
filling the opening with a metal fill.

18. The method of claim 17, wherein the reducing agent is hydrogen (H₂), carbon monoxide (CO), or combinations thereof.

19. The method of claim 17, wherein the carrier gas is helium (He).

20. The method of claim 17, wherein the conductive layer is made of tungsten (W), titanium (Ti), cobalt (Co), copper (Cu), nickel (Ni), ruthenium (Ru), aluminum (Al), tantalum (Ta), molybdenum (Mo), a metal alloy, or combinations thereof.
